(19) United States
(12) Patent Application Publication
(10) Pub. No.: US 2026/0291529 A1
(43) Pub. Date: Sep. 24, 2026

(54) HARMONIC REJECTION CALIBRATION FOR PASSIVE MIXER

(71) Applicant: QUALCOMM INCORPORATED, SAN DIEGO, CA (US)

(72) Inventor: Ojas CHOKSI, San Diego, CA (US)

(21) Appl. No.: 19/087,758

(22) Filed: Mar. 24, 2025

(51) Int. Cl. H04B 1/04; H03D 7/00; H04B 1/40

(52) U.S. Cl. CPC H04B 1/0475; H04B 1/40; H03D 7/00; H04B 2001/0408

(57) ABSTRACT

A passive mixer includes an in-phase (I) mixer and a quadrature (Q) mixer configured to receive a single-ended communication signal from a low noise amplifier (LNA), an in-phase (I) local oscillator (LO) signal provided to the I mixer and a quadrature (Q) LO signal applied to the Q mixer, a first pair of I resistance banks connected to selected outputs of the I mixer, and a second pair of Q resistance banks connected to selected outputs of the Q mixer, wherein the first pair of I resistance banks comprises an I+ resistance bank having at least one adjustable I+ resistance and an I− resistance bank having at least one adjustable I− resistance, and the second pair of Q resistance banks comprises a Q+ resistance bank having at least one adjustable Q+ resistance and a Q− resistance bank having at least one adjustable Q− resistance.

### FIELD

The present disclosure relates generally to electronics, and more specifically to a radio frequency (RF) phase shifter architecture.

### BACKGROUND

Wireless communication devices and technologies are becoming ever more prevalent, as are communication devices that operate at millimeter-wave (mmW) and near mmW frequencies. Wireless communication devices generally transmit and/or receive communication signals. In a radio frequency (RF) transceiver, a communication signal is typically amplified and transmitted by a transmit section and a received communication signal is amplified and processed by a receive section.

Modern wireless communication devices are capable of operating on many different communication bands, dictating multiple receive chains and transmit chains, and using multiple technologies such as GSM, WCDMA, LTE, 5GNR, WIFI, GNSS, mmWave, and using time division duplexing (TDD) and/or frequency division duplexing (FDD) modes, often with multiple-input, multiple-output (MIMO) antenna systems. Many of these technologies must coexist and operate simultaneously.

In addition, advances in lower deep submicron manufacturing technologies to save die area and minimize power consumption are resulting in ever shrinking package sizes, while the number of frequency band combinations and carrier signal frequencies keeps increasing, thus using additional receive chains.

In such a scenario, achieving high signal isolation is a challenge, particularly in situations where receiver sensitivity approaches −100 dBm. In such a scenario the n*LO (nth harmonic of the local oscillator) downconversion of various jammer signals from, for example, a transmit circuit, out of band jammers or WiFi, typically demands high isolation between the aggressor and the victim as well as good third order (3^{rd} LO, HR3) and fifth order (5^{th} LO, HR5) harmonic rejection.

Therefore, good LO harmonic rejection, particularly, good 3^{rd} order LO and 5^{th} order LO harmonic rejection is desired.

### SUMMARY

Various implementations of systems, methods and devices within the scope of the appended claims each have several aspects, no single one of which is solely responsible for the desirable attributes described herein. Without limiting the scope of the appended claims, some prominent features are described herein.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

One aspect of the disclosure provides a passive mixer including an in-phase (I) mixer and a quadrature (Q) mixer configured to receive a single-ended communication signal from a low noise amplifier (LNA), an in-phase (I) local oscillator (LO) signal provided to the I mixer and a quadrature (Q) LO signal applied to the Q mixer, a first pair of I resistance banks connected to selected outputs of the I mixer, and a second pair of Q resistance banks connected to selected outputs of the Q mixer, wherein the first pair of I resistance banks comprises an I+ resistance bank having at least one adjustable I+ resistance and an I− resistance bank having at least one adjustable I− resistance, and the second pair of Q resistance banks comprises a Q+resistance bank having at least one adjustable Q+ resistance and a Q− resistance bank having at least one adjustable Q− resistance.

Another aspect of the disclosure provides a method for harmonic signal rejection including providing a transmit (Tx) signal and a reference tone to a low noise amplifier, providing a single-ended communication signal from the low noise amplifier (LNA) to an in-phase (I) mixer and a quadrature (Q) mixer, providing an in-phase (I) local oscillator (LO) signal to the I mixer and a quadrature (Q) LO signal applied to the Q mixer, simultaneously sweeping a resistance value of at least one I+ resistance and at least one I− resistance to determine a resistance value corresponding to a maximum I harmonic rejection, and simultaneously sweeping a resistance value of at least one Q+ resistance and at least one Q− resistance to determine a resistance value corresponding to a maximum Q harmonic rejection.

Another aspect of the disclosure provides an apparatus for harmonic signal rejection including means for providing a transmit (Tx) signal and a reference tone to a low noise amplifier, means for providing a single-ended communication signal from the low noise amplifier (LNA) to an in-phase (I) mixer and a quadrature (Q) mixer, means for providing an in-phase (I) local oscillator (LO) signal to the I mixer and a quadrature (Q) LO signal applied to the Q mixer, means for simultaneously sweeping a resistance value of at least one I+ resistance and at least one I− resistance to determine a resistance value corresponding to a maximum I harmonic rejection, and means for simultaneously sweeping a resistance value of at least one Q+ resistance and at least one Q− resistance to determine a resistance value corresponding to a maximum Q harmonic rejection.

### BRIEF DESCRIPTION OF THE DRAWINGS

In the figures, like reference numerals refer to like parts throughout the various views unless otherwise indicated. For reference numerals with letter character designations such as “102a” or “102b”, the letter character designations may differentiate two like parts or elements present in the same figure. Letter character designations for reference numerals may be omitted when it is intended that a reference numeral encompass all parts having the same reference numeral in all figures.

FIG. 1 is a diagram showing a wireless device communicating with a wireless communication system.

FIG. 2A is a block diagram showing a wireless device in which exemplary techniques of the present disclosure may be implemented.

FIG. 2B is a block diagram showing a wireless device in which exemplary techniques of the present disclosure may be implemented.

FIG. 2C is a block diagram showing a wireless device in which exemplary techniques of the present disclosure may be implemented.

FIG. 3 is a diagram showing a passive mixer circuit.

FIG. 4 is a graph showing the effect of sweeping resistor values.

FIG. 5 is a diagram showing an example of performing HR3/HR5 calibration for the circuit of FIG. 3.

FIG. 6 is a diagram showing an alternative exemplary embodiment of a passive mixer circuit.

FIG. 7 is a flow chart describing an example of the operation of a method for performing harmonic rejection calibration.

FIG. 8 is a functional block diagram of an apparatus for performing harmonic rejection calibration.

### DETAILED DESCRIPTION

The word “exemplary” is used herein to mean “serving as an example, instance, or illustration.” Any aspect described herein as “exemplary” is not necessarily to be construed as preferred or advantageous over other aspects.

In accordance with an exemplary embodiment, a passive mixer with harmonic rejection calibration can compensate for third order local oscillator (3^{rd} LO) harmonics, fifth order local oscillator (5^{th} LO) harmonics, and other harmonics be selectively adjusting resistances at an output of the passive mixer.

In accordance with an exemplary embodiment, a passive mixer with harmonic rejection calibration can efficiently provide harmonic rejection at the third harmonic (HR3), at the fifth harmonic (HR5), or other harmonics.

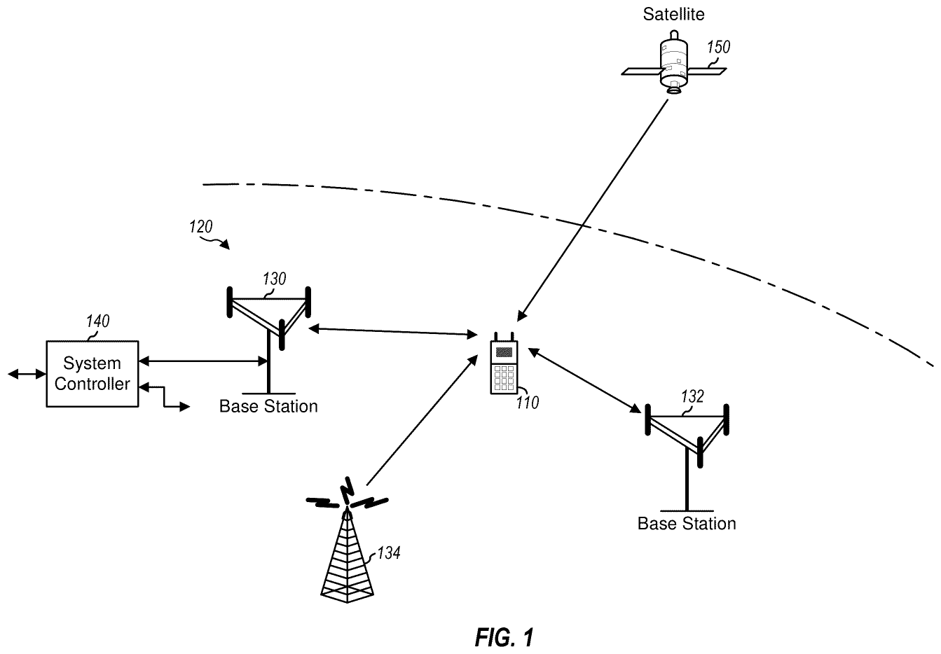

FIG. 1 is a diagram showing a wireless device 110 communicating with a wireless communication system 120. The wireless communication system 120 may be a Long Term Evolution (LTE) system, a Code Division Multiple Access (CDMA) system, a Global System for Mobile Communications (GSM) system, a wireless local area network (WLAN) system, a 5G NR (new radio) system, or some other wireless system. A CDMA system may implement Wideband CDMA (WCDMA), CDMA 1X, Evolution-Data Optimized (EVDO), Time Division Synchronous CDMA (TD-SCDMA), or some other version of CDMA. For simplicity, FIG. 1 shows wireless communication system 120 including two base stations 130 and 132 and one system controller 140. In general, a wireless communication system may include any number of base stations and any set of network entities.

The wireless device 110 may also be referred to as a user equipment (UE), a mobile station, a terminal, an access terminal, a subscriber unit, a station, etc. Wireless device 110 may be a cellular phone, a smartphone, a tablet, a wireless modem, a personal digital assistant (PDA), a handheld device, a laptop computer, a smartbook, a netbook, a tablet, a cordless phone, a medical device, an automobile, a device configured to connect to one or more other devices (for example through the internet of things), a wireless local loop (WLL) station, a Bluetooth device, etc. Wireless device 110 may communicate with wireless communication system 120. Wireless device 110 may also receive signals from broadcast stations (e.g., a broadcast station 134) and/or may communicate with satellites (e.g., a satellite 150 in one or more global navigation satellite systems (GNSS)), or a satellite that can receive signals from the wireless device 110, etc.). Wireless device 110 may support one or more radio technologies for wireless communication such as LTE, WCDMA, CDMA 1X, EVDO, TD-SCDMA, GSM, 802.11, 802.15, 5G, Sub 6 5G, 6G, UWB, etc.

Wireless device 110 may support carrier aggregation, for example as described in one or more LTE or 5G standards. In some embodiments, a single stream of data is transmitted over multiple carriers using carrier aggregation, for example as opposed to separate carriers being used for respective data streams. Wireless device 110 may be able to operate in a variety of communication bands including, for example, those communication bands used by LTE, WiFi, 5G or other communication bands, over a wide range of frequencies. Wireless device 110 may also be capable of communicating directly with other wireless devices without communicating through a network.

In general, carrier aggregation (CA) may be categorized into two types-intra-band CA and inter-band CA. Intra-band CA refers to operation on multiple carriers within the same band. Inter-band CA refers to operation on multiple carriers in different bands.

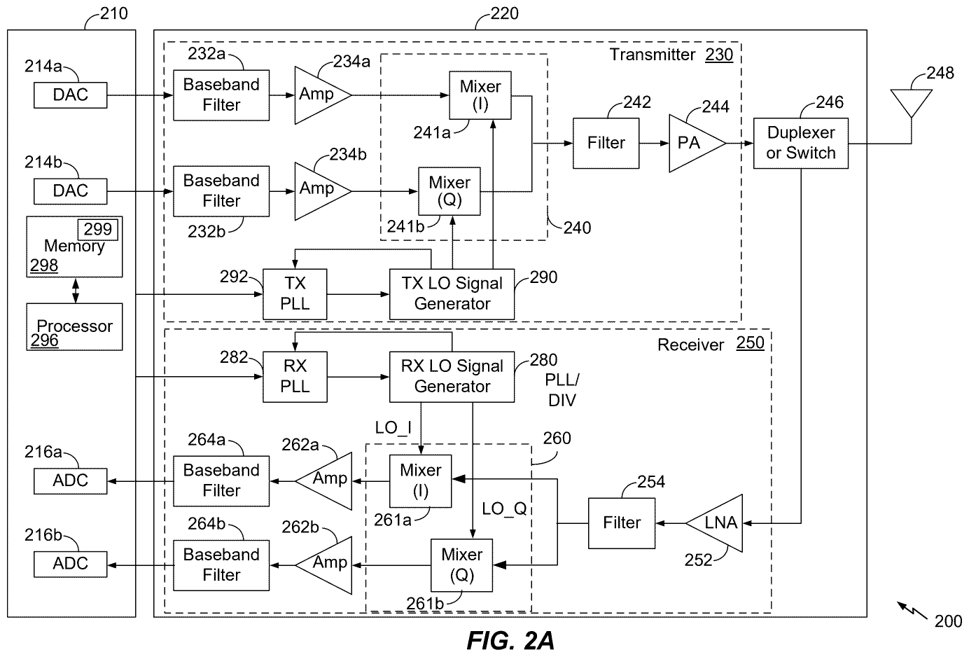

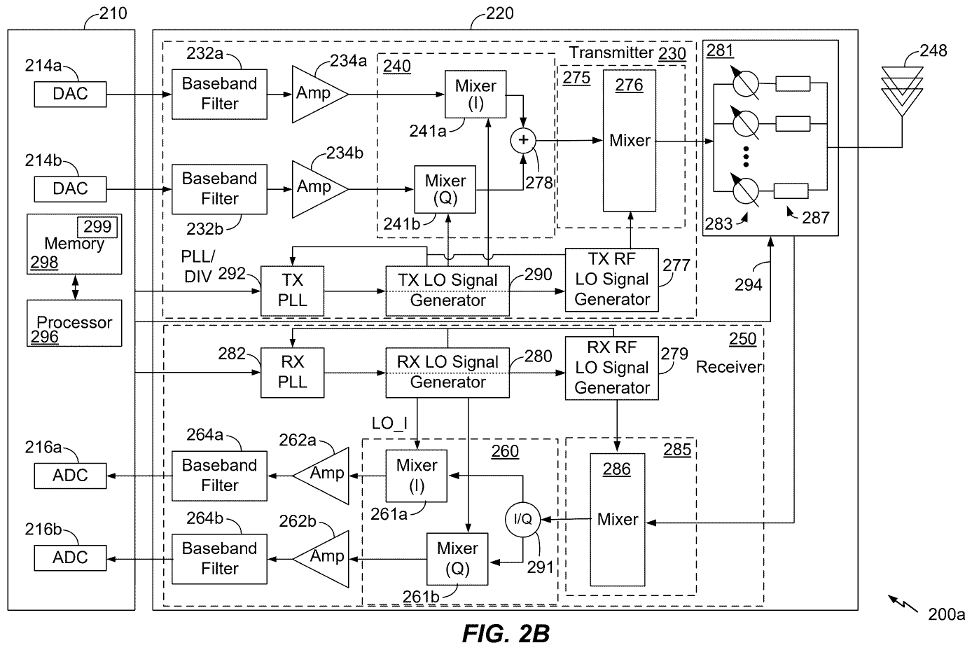

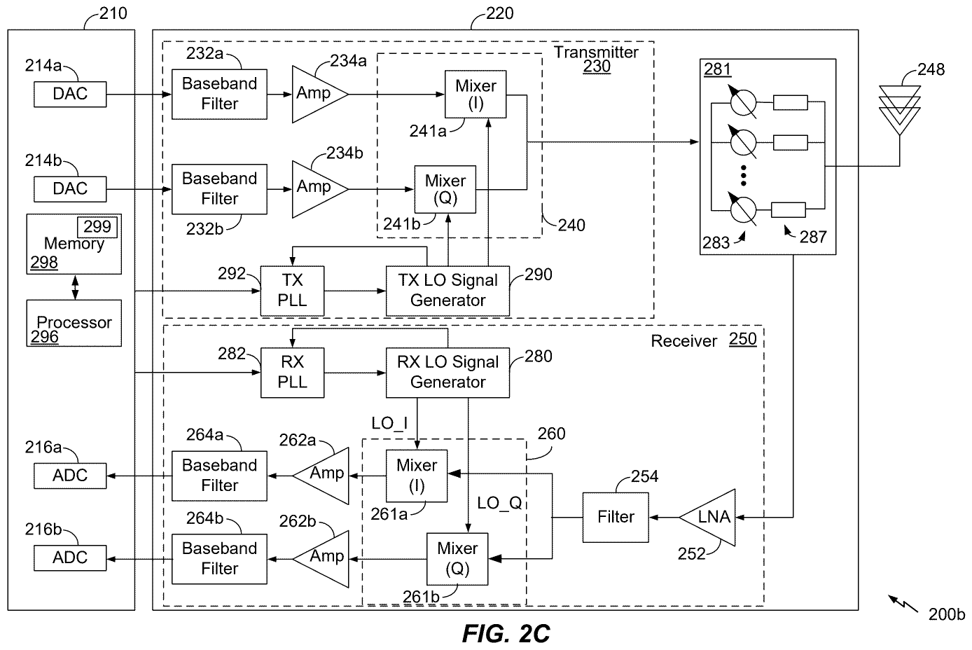

FIG. 2A is a block diagram showing a wireless device 200 in which exemplary techniques of the present disclosure may be implemented. The wireless device 200 may, for example, be an embodiment of the wireless device 110 illustrated in FIG. 1.

FIG. 2A shows an example of a transceiver 220 having a transmitter 230 and a receiver 250. In general, the conditioning of the signals in the transmitter 230 and the receiver 250 may be performed by one or more stages of amplifier, filter, upconverter, downconverter, etc. These circuit blocks may be arranged differently from the configuration shown in FIG. 2A. Furthermore, other circuit blocks not shown in FIG. 2A may also be used to condition the signals in the transmitter 230 and receiver 250. Unless otherwise noted, any signal in FIG. 2A, or any other figure in the drawings, may be either single-ended or differential. Some circuit blocks in FIG. 2A may also be omitted.

In the example shown in FIG. 2A, wireless device 200 generally comprises the transceiver 220 and a data processor 210. The data processor 210 may include a processor 296 operatively coupled to a memory 298. The memory 298 may be configured to store data and program codes shown generally using reference numeral 299 to denote a memory location, and may generally comprise analog and/or digital processing components. In some embodiments, a lookup table may be stored in the memory location 299 or the memory location 299 may otherwise comprise a lookup table having stored resistance values as will be described below. The processor 296 and the memory 298 may cooperate to control, configure, program, or otherwise fully or partially control some or all of the operation of the embodiments of the phase shifter with shared I/Q generator described herein.

The transceiver 220 includes a transmitter 230 and a receiver 250 that support bi-directional communication. In general, wireless device 200 may include any number of transmitters and/or receivers for any number of communication systems and frequency bands. All or a portion of the transceiver 220 may be implemented on one or more analog integrated circuits (ICs), RF ICs (RFICs), mixed-signal ICs, etc.

A transmitter or a receiver may be implemented with a super-heterodyne architecture or a direct-conversion architecture. In the super-heterodyne architecture, a signal is frequency-converted between radio frequency (RF) and baseband in multiple stages, e.g., from RF to an intermediate frequency (IF) in one stage, and then from IF to baseband in another stage for a receiver. In the direct-conversion architecture, a signal is frequency converted between RF and baseband in one stage. The super-heterodyne and direct-conversion architectures may use different circuit blocks and/or have different requirements. In the example shown in FIG. 2A, transmitter 230 and receiver 250 are implemented with the direct-conversion architecture.

In the transmit path, the data processor 210 processes data to be transmitted and provides in-phase (I) and quadrature (Q) analog output signals to the transmitter 230. In an exemplary embodiment, the data processor 210 includes digital-to-analog-converters (DAC's) 214a and 214b for converting digital signals generated by the data processor 210 into the I and Q analog output signals, e.g., I and Q output currents, for further processing. In other embodiments, the DACs 214a and 214b are included in the transceiver 220 and the data processor 210 provides data (e.g., for I and Q) to the transceiver 220 digitally.

Within the transmitter 230, baseband (e.g., lowpass) filters 232a and 232b filter the I and Q analog transmit signals, respectively, to remove undesired images caused by the prior digital-to-analog conversion. Amplifiers (Amp) 234a and 234b amplify the signals from baseband filters 232a and 232b, respectively, and provide I and Q baseband signals. An upconverter 240 having upconversion mixers 241a and 241b upconverts the I and Q baseband signals with I and Q transmit (TX) local oscillator (LO) signals from a TX LO signal generator 290 and provides an upconverted signal. A filter 242 filters the upconverted signal to remove undesired images caused by the frequency upconversion as well as noise in a receive frequency band. A power amplifier (PA) 244 amplifies the signal from filter 242 to obtain the desired output power level and provides a transmit RF signal. The transmit RF signal may be routed through a duplexer or switch 246 and transmitted via an antenna 248. While examples discussed herein utilize I and Q signals, those of skill in the art will understand that components of the transceiver may be configured to utilize polar modulation.

In the receive path, antenna 248 receives communication signals and provides a received RF signal, which may be routed through duplexer or switch 246 and provided to a low noise amplifier (LNA) 252. The duplexer 246 is designed to operate with a specific RX-to-TX duplexer frequency separation, such that RX signals are isolated from TX signals. The received RF signal is amplified by LNA 252 and filtered by a filter 254 to obtain a desired RF input signal.

Downconversion mixers 261a and 261b in a downconverter 260 mix the output of filter 254 with I and Q receive (RX) LO signals (i.e., LO_I and LO_Q) from an RX LO signal generator 280 to generate I and Q baseband signals. The I and Q baseband signals are amplified by amplifiers 262a and 262b and further filtered by baseband (e.g., lowpass) filters 264a and 264b to obtain I and Q analog input signals, which are provided to data processor 210. In the exemplary embodiment shown, the data processor 210 includes analog-to-digital-converters (ADC's) 216a and 216b for converting the analog input signals into digital signals to be further processed by the data processor 210. In some embodiments, the ADCs 216a and 216b are included in the transceiver 220 and provide data to the data processor 210 digitally.

In FIG. 2A, TX LO signal generator 290 generates the I and Q TX LO signals used for frequency upconversion, while RX LO signal generator 280 generates the I and Q RX LO signals used for frequency downconversion. Each LO signal is a periodic signal with a particular fundamental frequency. A phase locked loop (PLL) 292 receives timing information from data processor 210 and generates a control signal used to adjust the frequency and/or phase of the TX LO signals from LO signal generator 290. Similarly, a PLL 282 receives timing information from data processor 210 and generates a control signal used to adjust the frequency and/or phase of the RX LO signals from LO signal generator 280.

Wireless device 200 may support CA and may (i) receive multiple downlink signals transmitted by one or more cells on multiple downlink carriers at different frequencies and/or (ii) transmit multiple uplink signals to one or more cells on multiple uplink carriers. Those of skill in the art will understand, however, that aspects described herein may be implemented in systems, devices, and/or architectures that do not support carrier aggregation.

Certain components of the transceiver 220 are functionally illustrated in FIG. 2A, and the configuration illustrated therein may or may not be representative of a physical device configuration in certain implementations. For example, as described above, transceiver 220 may be implemented in various integrated circuits (ICs), RF ICs (RFICs), mixed-signal ICs, etc. In some embodiments, the transceiver 220 is implemented on a substrate or board such as a printed circuit board (PCB) having various modules, chips, and/or components. For example, the power amplifier 244, the filter 242, and the duplexer 246 may be implemented in separate modules or as discrete components, while the remaining components illustrated in the transceiver 220 may be implemented in a single transceiver chip.

The power amplifier 244 may comprise one or more stages comprising, for example, driver stages, power amplifier stages, or other components, that can be configured to amplify a communication signal on one or more frequencies, in one or more frequency bands, and at one or more power levels. Depending on various factors, the power amplifier 244 can be configured to operate using one or more driver stages, one or more power amplifier stages, one or more impedance matching networks, and can be configured to provide good linearity, efficiency, or a combination of good linearity and efficiency.

In an exemplary embodiment in a super-heterodyne architecture, the PA 244 and LNA 252 (and filter 242 and filter 254 in some examples) may be implemented separately from other components in the transmitter 230 and receiver 250, for example on a millimeter wave integrated circuit. An example super-heterodyne architecture is illustrated in FIG. 2B.

FIG. 2B is a block diagram showing a wireless device in which exemplary techniques of the present disclosure may be implemented. Certain components, for example which may be indicated by identical reference numerals, of the wireless device 200a in FIG. 2B may be configured similarly to those in the wireless device 200 shown in FIG. 2A and the description of identically numbered items in FIG. 2B will not be repeated.

The wireless device 200a is an example of a heterodyne (or superheterodyne) architecture in which the upconverter 240 and the downconverter 260 are configured to process a communication signal between baseband and an intermediate frequency (IF). The IF signal may be a low IF (LIF) signal, or a zero (or near zero) IF (ZIF) signal. For example, the upconverter 240 may include a summing function 278 and may be configured to provide an IF signal to an upconverter 275. In an exemplary embodiment, the upconverter 275 may comprise upconversion mixer 276. The summing function 278 combines the I and the Q outputs of the upconverter 240 and provides a non-quadrature signal to the mixer 276. The non-quadrature signal may be single ended or differential. The mixer 276 is configured to receive the IF signal from the upconverter 240 and TX RF LO signals from a TX RF LO signal generator 277, and provide an upconverted RF signal to phase shift circuitry 281. While PLL 292 is illustrated in FIG. 2B as being shared by the signal generators 290, 277, a respective PLL for each signal generator may be implemented.

In an exemplary embodiment, components in the phase shift circuitry 281 may comprise one or more adjustable or variable phased array elements, and may receive one or more control signals from the data processor 210 over connection 294 and operate the adjustable or variable phased array elements based on the received control signals.

In an exemplary embodiment, the phase shift circuitry 281 comprises phase shifters 283 and phased array elements 287. Although three phase shifters 283 and three phased array elements 287 are shown for ease of illustration, the phase shift circuitry 281 may comprise more or fewer phase shifters 283 and phased array elements 287. For example, one or two arrays of four or five antennas and corresponding phase shifters/phased array elements may be implemented.

Each phase shifter 283 may be configured to receive the RF transmit signal from the upconverter 275, alter the phase by an amount, and provide the RF signal to a respective phased array element 287. Each phased array element 287 may comprise transmit and receive circuitry including one or more filters, amplifiers, driver amplifiers, low noise amplifiers, and/or power amplifiers. In some embodiments, the phase shifters 283 may be incorporated within respective phased array elements 287.

The output of the phase shift circuitry 281 is provided to an antenna array 248. In an exemplary embodiment, the antenna array 248 comprises a number of antennas that typically correspond to the number of phase shifters 283 and phased array elements 287, for example such that each antenna element is coupled to a respective phased array element 287. In an exemplary embodiment, the phase shift circuitry 281 and the antenna array 248 may be referred to as a phased array.

In a receive direction, an output of the phase shift circuitry 281 is provided to a downconverter 285. In an exemplary embodiment, the downconverter 285 may comprise a downconversion mixer 286. In an exemplary embodiment, the mixer 286 downconverts the receive RF signal provided by the phase shift circuitry 281 to an IF signal according to RX RF LO signals provided by an RX RF LO signal generator 279. The downconverter 260 includes an I/Q generation function 291. The I/Q generation function 291 receives the IF signal from the mixer 286 and generates I and Q signals for the downconverter 260, which downconverts the IF signals to baseband, as described above. While PLL 282 is illustrated in FIG. 2B as being shared by the signal generators 280, 279, a respective PLL for each signal generator may be implemented.

In some embodiments, the upconverter 275, downconverter 285, and the phase shift circuitry 281 are implemented on a common IC. In some embodiments, the summing function 278 and the I/Q generation function 291 are implemented separate from the mixers 276 and 286 such that the mixers 276, 286 and the phase shift circuitry 281 are implemented on the common IC, but the summing function 278 and I/Q generation function 291 are not (e.g., the summing function 278 and I/Q generation function 291 are implemented in another IC coupled to the IC having the mixers 276, 286). In some embodiments, the LO signal generators 277, 279 are included in the common IC. In some embodiments in which phase shift circuitry is implemented on a common IC with 276, 286, 277, 278, 279, and/or 291, the common IC and the antenna array 248 are included in a module, which may be coupled to other components of the transceiver 220 via a connector. In some embodiments, the phase shift circuitry 281, for example, a chip on which the phase shift circuitry 281 is implemented, is coupled to the antenna array 248 by an interconnect or both are mounted to a substrate. For example, components of the antenna array 248 may be implemented on a substrate and coupled to an integrated circuit implementing the phase shift circuitry 281 via a flexible printed circuit or the integrated circuit may be mounted to an opposite side of the substrate.

In some embodiments, both the architecture illustrated in FIG. 2A and the architecture illustrated in FIG. 2B are implemented in the same device. For example, a wireless device 110 or 200 may be configured to communicate with signals having a frequency below about 20 GHz using the architecture illustrated in FIG. 2A and to communicate with signals having a frequency above about 20 GHz using the architecture illustrated in FIG. 2B. In devices in which both architectures are implemented, one or more components of FIGS. 2A and 2B that are identically numbered may be shared between the two architectures. For example, both signals that have been downconverted directly to baseband from RF and signals that have been downconverted from RF to baseband via an IF stage may be filtered by the same baseband filter 264. In other embodiments, a first version of the filter 264 is included in the portion of the device which implements the architecture of FIG. 2A and a second version of the filter 264 is included in the portion of the device which implements the architecture of FIG. 2B. While certain example frequencies are described herein, other implementations are possible. For example, signals having a frequency above about 20 GHz (e.g., having a mmW frequency) may be transmitted and/or received using a direct conversion architecture. In such embodiments, for example, a phased array may be implemented in the direct conversion architecture.

FIG. 2C is a block diagram showing a wireless device in which exemplary techniques of the present disclosure may be implemented. Certain components, for example which may be indicated by identical reference numerals, of the wireless device 200b in FIG. 2C may be configured similarly to those in the wireless device 200 shown in FIG. 2A and/or the wireless device 200a shown in FIG. 2B and the description of identically numbered items in FIG. 2C will not be repeated.

The wireless device 200b in FIG. 2C incorporates the phase shift circuitry 281 (of FIG. 2B) in a direct conversion architecture, where mmW transmission signals are upconverted and downconverted between baseband and RF without the use of intermediate frequency (IF) signal conversion. For example, the LO signals in the architecture of FIG. 2C may comprise signals at frequencies of tens of GHz.

In some embodiments, the upconverter 240, downconverter 260, and the phase shift circuitry 281 are implemented on a common IC. In some embodiments, the LO signal generators 280, 290 are included in the common IC. In some embodiments, the common IC and the antenna array 248 are included in a module, which may be coupled to other components of the transceiver 220 via a connector. In some embodiments, the phase shift circuitry 281, for example, a chip on which the phase shift circuitry 281 is implemented, is coupled to the antenna array 248 by an interconnect or both are mounted to a substrate. For example, components of the antenna array 248 may be implemented on a substrate and coupled to an integrated circuit implementing the phase shift circuitry 281 via a flexible printed circuit or the integrated circuit may be mounted to an opposite side of the substrate.

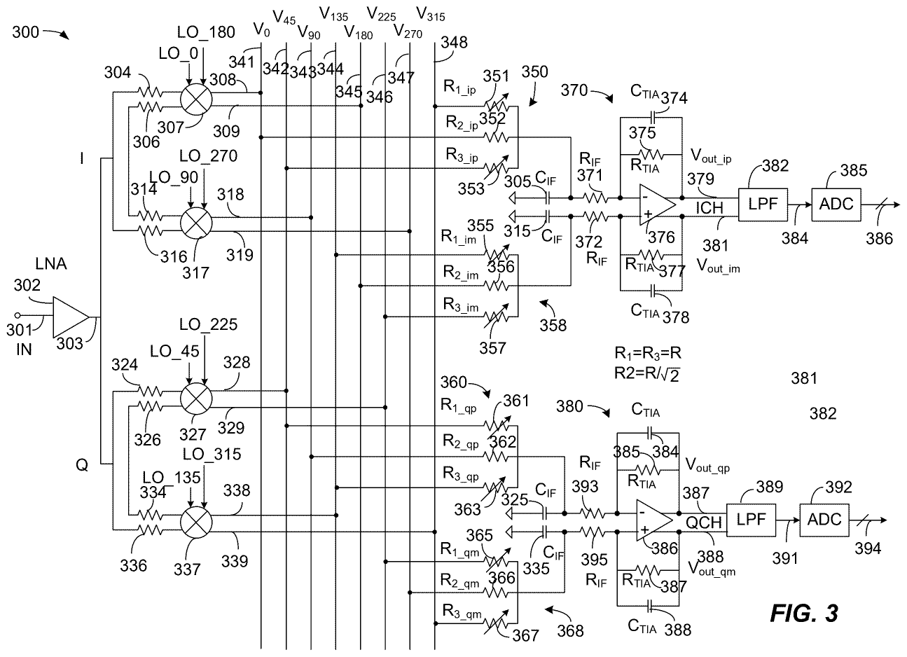

FIG. 3 is a diagram 300 showing a passive mixer circuit. Passive mixers operating in current mode offer superior performance to active mixers due to absence of flicker noise and good linearity when driven by a high voltage swing LO signal. However, mixers are susceptible to creating interference to the desired signal from the downconversion of jammer signals (modulated spurious signals) or continuous wave (CW) signals (CW spurious signals) occurring at or near the third and fifth harmonics of the LO signal. These unwanted downconverted signals may desensitize the receiver and interfere with the desired receive signal. In an exemplary embodiment, the passive mixer circuit 300 comprises an I/Q mixer. A low noise amplifier (LNA) 302 receives an input signal over connection 301. The input signal may be a radio frequency (RF) input signal or may be an intermediate frequency (IF) signal. In an exemplary embodiment, the output of the LNA 302 is a single-ended signal on connection 303 and is provided to mixers 307, 317, 327 and 337. For example, the signal on connection 303 may be provided to the mixer 307 through a resistance 304, may be provided to the mixer 317 through a resistance 316, may be provided to the mixer 327 through a resistance 324, and may be provided to the mixer 337 through a resistance 336. Another input to the mixer 307 and the mixer 317 are connected through resistances 306 and 314 in what is referred to as a double balanced mixer with a floating input architecture. Similarly, another input to the mixer 327 and the mixer 337 are connected through resistances 326 and 334 in what is referred to as a double balanced mixer with a floating input architecture.

As shown in FIG. 3, a double balanced mixer with a floating input offers the advantage of avoiding the use of a large balun to convert the single-ended LNA output to a differential mixer input, while maintaining the LO symmetry to the IF port for good linearity and noise. The resistors 304, 306, 314, 316, 324, 326, 334, and 336 at the RF port of the mixer help linearize the nonlinear switch resistance of the passive mixer, thus providing good linearity. Further, such an architecture provides good noise isolation between the I mixers 307 and 317 and between the Q mixers 327 and 337 when the LO waveforms of various phases have a finite overlap.

In an exemplary embodiment, the mixer 307 and the mixer 317 are configured to process an in-phase (I) signal. In an exemplary embodiment, the mixer 307 is configured to receive a local oscillator (LO) signal corresponding to 0 degrees and 180 degrees, and the mixer 317 is configured to receive a local oscillator (LO) signal corresponding to 90 degrees and 270 degrees. The LO signals may be provided by the RX PLL 282 and the RX LO signal generator 279/280 of FIGS. 2A, 2B, 2C or by another LO signal generator.

In an exemplary embodiment, the mixer 327 and the mixer 337 are configured to process a quadrature (Q) signal. In an exemplary embodiment, the mixer 327 is configured to receive a local oscillator (LO) signal corresponding to 45 degrees and 225 degrees, and the mixer 337 is configured to receive a local oscillator (LO) signal corresponding to 135 degrees and 315 degrees. The LO signals may be provided by the RX PLL 282 and the RX LO signal generator 279/280 of FIGS. 2A, 2B, 2C or by another LO signal generator.

In an exemplary embodiment, the outputs of the mixers 307, 317, 327 and 337 are connected to a plurality of voltage lines corresponding to the 0, 45, 90, 135, 180, 225, 270 and 315 degree outputs. For example, the 0 degree output of the mixer 307 is connected to the V₀ line 341 and the 180 degree output is connected to the V₁₈₀ line 345. The 90 degree output of the mixer 317 is connected to the V₉₀ line 343 and the 270 degree output is connected to the V₂₇₀ line 347. Similarly, the 45 degree output of the mixer 327 is connected to the V₄₅ line 342 and the 225 degree output is connected to the V₂₂₅ line 346, and the 135 degree output of the mixer 337 is connected to the V₁₃₅ line 344 and the 315 degree output is connected to the V₃₁₅ line 348.

In an exemplary embodiment, a first resistance bank 350 comprises resistances 351, 352 and 353 and a second resistance bank 358 comprises resistances 355, 356 and 357. In an exemplary embodiment, the resistance 351 is an adjustable resistance and has a value R_{1_ip}, the resistance 352 is a fixed resistance having the value R_{2_ip}, and the resistance 353 is an adjustable resistance having the value R_{3_ip}. In an exemplary embodiment, the resistance 355 is an adjustable resistance and has a value R_{1_im}, the resistance 356 is a fixed resistance having the value R_{2_im}, and the resistance 357 is an adjustable resistance having the value R_{3_im}. In an exemplary embodiment, the designation “ip” refers to a positive (+) in-phase (I+) differential signal and the designation “im” refers to a minus (−) in-phase (I−) differential signal. In an exemplary embodiment, the values of the adjustable resistances 351, 353, 355 and 357 can be set or controlled by the data processor 210 of FIGS. 2A, 2B or 2C, or by another controller. In an exemplary embodiment, as will be described in greater detail below, the values of the resistances 351 and 355 are swept simultaneously as part of harmonic rejection ratio (HRR) optimization, and the values of the resistances 353 and 357 are swept simultaneously as part of HRR optimization. In an exemplary embodiment, the weighting of the resistances 351 (R_{1_ip}), 352 (R_{2_ip}), 353 (R_{3_ip}) and the weighting of the resistances 355 (R_{1_im}), 356 (R_{2_ im}), 357 (R_{3_im}) correspond to (1, 1/sqrt (2), 1), where the resistances 351 (R_{1_ip}), and 353 (R_{3_ip}) are adjustable and the resistance 352 (R_{2_ip}), is fixed and where the resistances 355 (R_{1_im}) and 357 (R_{3_im}) are adjustable and the resistance 356 (R_{2_im}) is fixed.

In an exemplary embodiment, a third resistance bank 360 comprises resistances 361, 362 and 363, and a fourth resistance bank 368 comprises resistances 365, 366 and 367. In an exemplary embodiment, the resistance 361 is an adjustable resistance and has a value R_{1_qp}, the resistance 362 is a fixed resistance having the value R_{2_qp}, and the resistance 363 is an adjustable resistance having the value R_{3_qp}. In an exemplary embodiment, the resistance 365 is an adjustable resistance and has a value R_{1_qm}, the resistance 366 is a fixed resistance having the value R_{2_qm}, and the resistance 367 is an adjustable resistance having the value R_{3_qm}. In an exemplary embodiment, the designation “qp” refers to a positive (+) quadrature (Q+) differential signal and the designation “qm” refers to a minus (−) quadrature (Q−) differential signal. In an exemplary embodiment, the value of the adjustable resistances can be set or controlled by the data processor 210 of FIGS. 2A, 2B or 2C, or by another controller. In an exemplary embodiment, as will be described in greater detail below, the values of the resistances 361 and 365 are swept simultaneously as part of HRR optimization, and the values of the resistances 363 and 367 are swept simultaneously as part of HRR optimization. In an exemplary embodiment, the weighting of the resistances 361 (R_{1_qp}), 362 (R_{2_qp}), 363 (R_{3_qp}) and the weighting of the resistances 365 (R_{1_qm}), 366 (R_{2_qm}), 367 (R_{3_qm}) correspond to (1, 1/sqrt (2), 1), where the resistances 361 (R_{1_qp}), and 363 (R_{3_qp}) are adjustable and the resistance 362 (R_{2_qp}), is fixed and where the resistances 365 (R_{1_qm}) and 367 (R_{3_qm}) are adjustable and the resistance 366 (R_{2_qm}) is fixed.

In an exemplary embodiment, the first resistance bank 350 is connected to an inverting input of a transimpedance amplifier (TIA) 370 and the second resistance bank 358 is connected to a non-inverting input of the TIA 370. The inverting input of the TIA 370 is connected to a system ground through a resistance 371 (R_{IF}) and a capacitance 305 (C_{IF}). The non-inverting input of the TIA 370 is connected to a system ground through a resistance 372 (R_{IF}) and a capacitance 315 (C_{IF}). The TIA 370 includes an amplifier 376, feedback resistances 375 (RTIA) and 377 (R_{TIA}), and feedback capacitances 374 (C_{TIA}) and 378 (C_{TIA}). The I-channel (ICH) output of the TIA 370 is provided over connections 379 (V_{out_ip}) and 381 (V_{out_im}).

The outputs on connections 379 and 381 are provided to a low pass filter (LPF) 382 and the output of the LPF 382 is provided over connection 384 to an analog-to-digital converter (ADC) 385. The output of the ADC 385 is provided over connection 386 and is generally a digital signal provided to baseband circuitry for further processing.

In an exemplary embodiment, the third resistance bank 360 is connected to an inverting input of a TIA 380 and the fourth resistance bank 368 is connected to a non-inverting input of the TIA 380. The inverting input of the TIA 380 is connected to a system ground through a resistance 393 (R_{IF}) and a capacitance 325 (C_{IF}). The non-inverting input of the TIA 380 is connected to a system ground through a resistance 395 (R_{IF}) and a capacitance 335 (C_{IF}). The TIA 380 includes an amplifier 386, feedback resistances 385 (R_{TIA}) and 387 (R_{TIA}), and feedback capacitances 384 (C_{TIA}) and 388 (C_{TIA}). The Q-channel (QCH) output of the TIA 380 is provided over connections 387 (V_{out_qp}) and 388 (V_{out_qm}).

The outputs on connections 387 and 388 are provided to an LPF 389 and the output of the LPF 389 is provided over connection 391 to an ADC 392. The output of the ADC 392 is provided over connection 394 and is generally a digital signal provided to baseband circuitry for further processing.

In an exemplary embodiment, the resistances (R_{IF}) 371, 372, 393, and 395 at the TIA inputs reduce the TIA flicker noise by increasing the impedance at the mixer outputs and offer good baseband (BB) linearity over wide bandwidth (BW) in the presence of TIA nonlinear impedance. The capacitances (C_{IF}) 305, 315, 325, and 335 implement a filter pole with the respective resistances (R_{IF}) 371, 372, 393, and 395 to filter out any components of a downconverted transmit signal at the duplex frequency offset, thus improving the linearity of the mixer and preventing the saturation/compression of the TIA under high gain.

In an exemplary embodiment, the passive mixer circuit 300 implements a harmonic rejection mixer (HRM) using only four passive mixers 307, 317, 327 and 337, thereby reducing the LO power and die area.

In an exemplary embodiment, the passive mixer circuit 300 can be used for calibrating either third order LO harmonics (HR3) or fifth order LO harmonics (HR5) by selectively adjusting the values of adjustable resistances 351, 353, 355, 357, 361, 363, 365 and 367, thereby greatly improving HR3, (or HR5) depending upon the use case. This resistor adjustment entails selectively adjusting the values of the resistances 351, 353, 355, 357, 361, 363, 365 and 367 and can compensate not only the I and Q signal mismatches in the mixer but also the gain/phase errors in the LO path.

Calibration of third (HR3) and fifth (HR5) order harmonics can be done by injecting a transmit (Tx) tone and a reference tone into the LNA 302 in a receiver (Rx) at 3rd LO or 5th LO to optimize HR3 or HR5. The calibrated resistor codes/values can be stored in a lookup table, such as in the memory 298 or memory location 299 of FIGS. 2A, 2B, 2C, for various communications bands and in some embodiments be used as a “per-part” calibration or as a static lookup table for all parts.

In an exemplary embodiment, the resistances 351, 353, 355, 357, 361, 363, 365 and 367 can be implemented with a resistor bank and on/off switches or can use analog voltage-on switches, or other adjustable resistance structures, to fine tune the resistance value of the resistances.

To perform calibration, in an exemplary embodiment, a Tx tone can be injected at the input of the LNA 302 at 3^{rd} LO (for HR3) or at 5^{th} LO (for HR5) along with an in-band reference signal tone. In an exemplary embodiment, the Tx tone can be generated by the transmitter 230 (FIGS. 2A, 2B,2C) at the 3^{rd} harmonic or 5^{th} harmonic of the RxLO. In an exemplary embodiment, the in-band reference signal tone may be generated by a signal generator, such as the TX PLL 292 of FIGS. 2A, 2B, 2C, or another signal generator. For example, the TX PLL 292 can generate an in-band reference signal tone (for example, within 3 dB BW of the signal path) as well as the Tx tone (at the 3^{rd} harmonic or 5^{th} harmonic of the RxLO) for injection into the LNA input on connection 301. The Tx tone generally lies out of band. This Tx tone is not a Tx signal of the same band at the duplex offset. This Tx tone is the Tx tone of another band (acting as jammer) and can be downconverted unintentionally due to 3^{rd} harmonic or 5^{th} harmonic of the RxLO signal. The in-band reference signal tone allows the harmonic rejection to be measured in dB. However, obtaining the harmonic rejection in dB is optional and the 3^{rd} harmonic or the 5^{th} harmonic tone can be minimized by sweeping the adjustable resistors (351, 353, 355, 357, 361, 363, 365, 367) by measuring the power at the ADC output as a dBm number.

The values of the resistances 351 (R_{1_ip}) and 355 (R_{1_im}) are then simultaneously swept to find the optimum HR3 (or HR5) by analyzing the output of the ADC 385. The optimum resistance value is referred to as R_{1_ich_opt}. For example, the in-band reference signal tone is injected at the LNA input, along with the Tx tone at for example the 3^{rd} harmonic (or 5^{th} harmonic), where both the in-band reference signal tone and the Tx tone have the same power. The ratio of the in-band reference signal tone to the Tx tone (at HR3 in this example) power at the ADC output provides the HR3 harmonic rejection in dB. However, in this exemplary embodiment, harmonic rejection in dB is not measured. In this example, only the output power of Tx tone (HR3 tone) (in dBm) is minimized by adjusting the values of the resistances 351 (R_{1_ip}) and 355 (R_{1_im}), and other adjustable resistances as described below. This assumes that the in-band signal gain is not affected. Using an in-band reference signal tone and measuring in dB the rejection of the HR3 Tx tone to the in-band reference signal tone provides an accurate result.

The optimum value, R_{1_ich_opt}, for the resistance 351 (R_{1_ip}) and the resistance 355 (R_{1_im}) is then set.

Next, the resistances 361 (R_{1_qp}) and 365 (R_{1_qm}) are then simultaneously swept to find the optimum HR3 by analyzing the output of the ADC 392, as described above with respect to the ADC 385. The optimum resistance value is referred to as R_{1_qch_opt}.

The optimum value, R_{1_qch_opt}, for the resistance 361 (R_{1_qp}) and the resistance 365 (R_{1_qm}) is then set.

Next, the resistance 353 (R_{3_ip}) and the resistance 357 (R_{3_im}) are then simultaneously swept while keeping the resistance 351 (R_{1_ip})=355 (R_{1_im})=R_{1_ich_opt} and keeping the resistance 361 (R_{1_qp})=365 (R_{1_qm})=R_{1_qch_opt} to find the optimum HR3 by analyzing the output of the ADC 385, as described above. The optimum resistance value is referred to as R_{3_ich_opt}.

Next, the resistance 363 (R_{3_qp}) and the resistance 367 (R_{3_qm}) are then simultaneously swept while keeping the resistance 351 (R_{1_ip})=355 (R_{1_im})=R_{1_ich_opt}, keeping the resistance 361 (R_{1_qp})=365 (R_{1_qm})=R_{1_qch_opt} and keeping the resistance 353 (R_{3_ip})=357 (R_{3_im})=R_{3_ich_opt}, to find the optimum HR3 by analyzing the output of the ADC 385, as described above. The optimum resistance value is referred to as R_{3_qch_opt}.

As mentioned above, the value of the resistances 352, 356, 362 and 366 are fixed and are 1/sqrt(2) when the resistance values for the resistances 351, 353, 355, 357, 361, 363, 365 and 367 are 1.

In an exemplary embodiment, nominally, the values of the resistances R1, R2, R3 ((351 (R_{1_ip}), 352 (R_{2_ip}), 353 (R_{3_ip}); (355 (R_{1_im}), 356 (R_{2_im}), 357 (R_{3_im}); (361 (R_{1_qp}), 362(R_{2_qp} ), 363 (R_{3_qp}); (365 (R_{1_qm}), 366 (R_{2_qm} ), 367 (R_{3_qm})) are set in the ratio of 1, 1/sqrt(2), 1. However, due to mismatches, this ratio may not be maintained. The calibration described herein is used to adjust the resistors R1 and R3 to obtain that ratio and hence the desired HR3 (or HR5) harmonic rejection.

These calibrated resistor codes/values can be stored in a lookup table in the memory 298 for various bands and be used as a per-part calibration or a static lookup table for all parts.

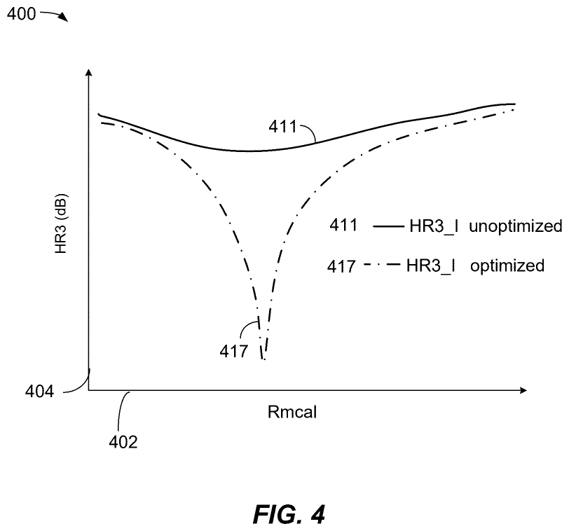

FIG. 4 is a graph 400 showing the effect of sweeping resistor values. The graph 400 includes a horizontal axis 402 showing resistance (Rmcal) (OJAS, WHAT DOES THE “m” IN Rm CAL MEAN?) increasing to the right and a vertical axis 404 showing harmonic rejection (in dB) decreasing upwardly. The graph 400 shows an exemplary embodiment where the resistance value of one of the adjustable resistances of FIG. 3 is swept to determine a maximum HR3 (in this example) value.

A trace 411 shows an exemplary third order harmonic rejection (HR3) for an unoptimized HR3 and the trace 417 shows an exemplary third order harmonic rejection (HR3) for an optimized HR3.

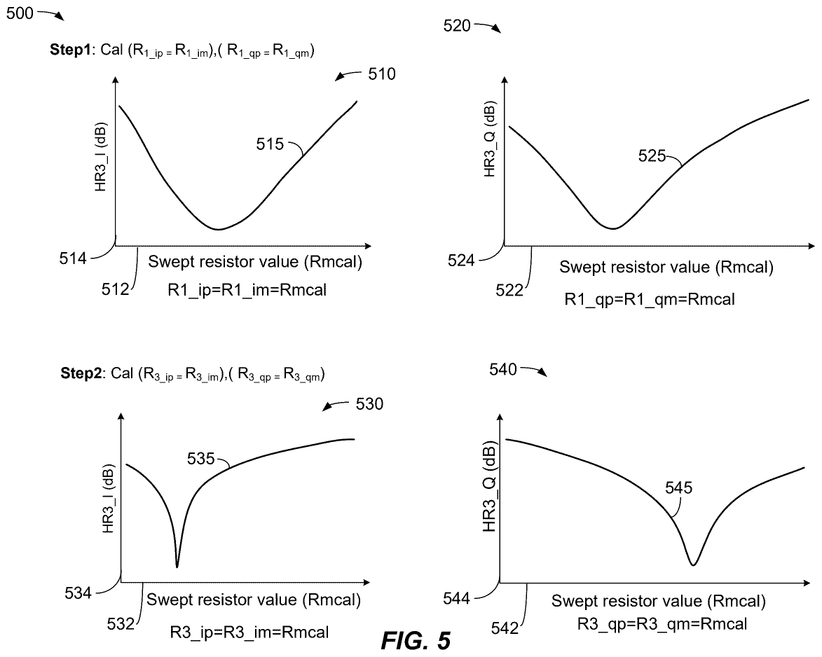

FIG. 5 is a diagram 500 showing an example of performing HR3/HR5 calibration for the circuit of FIG. 3. The graphs 510 and 520 show a case where the values of the resistances 351 (R_{1_ip}) and 355 (R_{1_im}) are swept to determine an optimum value for HR3_I (R_{1_ip}=R_{1_im}) and where the values of the resistances 361 (R_{1_qp}) and 365 (R_{1_qm}) are swept to determine an optimum value for HR3_Q (R_{1_qp}=R_{1_qm}).

The graph 510 shows a trace 515 showing HR3 for the in-phase signal (HR3_I) and has a horizontal axis 512 showing swept resistance value (Rmcal) increasing to the right and a vertical axis 514 showing third order harmonic rejection (HR3_I in dB) decreasing upwardly.

The graph 520 shows a trace 525 showing HR3 for the quadrature signal (HR3_Q) using the optimum resistor value R_{1_ich_opt} for R1_ip, R1_im from the graph 510 and has a horizontal axis 522 showing swept resistance value (Rmcal) increasing to the right and a vertical axis 524 showing third order harmonic rejection (HR3_Q in dB) decreasing upwardly.

The graph 530 shows a trace 535 showing HR3 for the in-phase signal (HR3_I) using the optimum value R1_ich_opt for R1_ip, R1_im from the graph 510 and optimum R1_qch_op for R1_qp and R1_qm from the graph 520 and has a horizontal axis 532 showing swept resistance value (Rmcal) increasing to the right and a vertical axis 534 showing third order harmonic rejection (HR3_I in dB) decreasing upwardly.

The graph 540 shows a trace 545 showing HR3 for the quadrature signal (HR3_Q) using the optimum R1_ich_opt for R1_ip, R1_im from the graph 510, optimum R1_qch_opt for R1_qp, R1_qm from the graph 520, and optimum R3_ich_opt for R3_ip, R3_im from the graph 530 and has a horizontal axis 542 showing swept resistance value (Rmcal) increasing to the right and a vertical axis 544 showing third order harmonic rejection (HR3_Q in dB) decreasing upwardly.

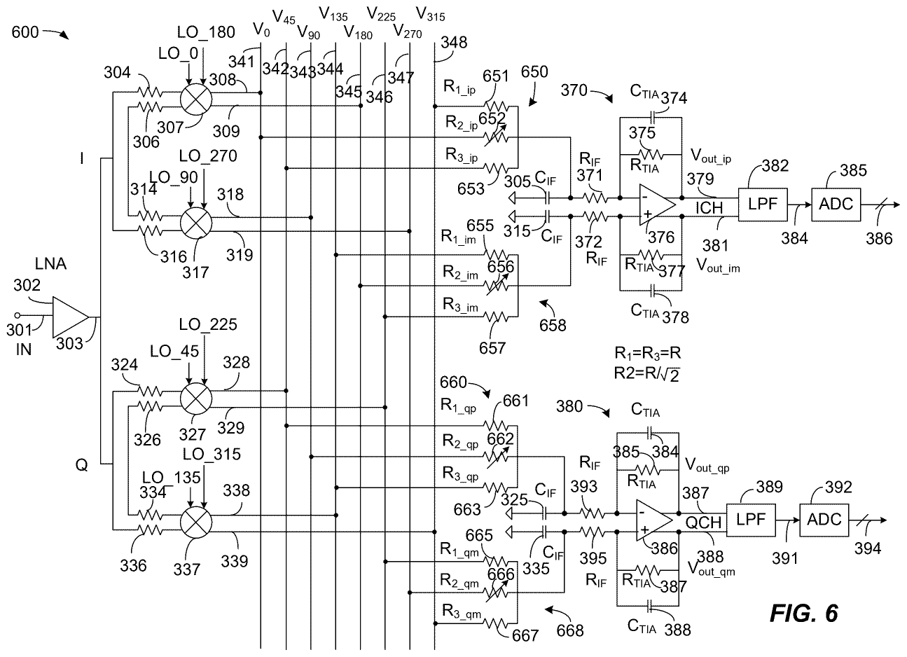

FIG. 6 is a diagram 600 showing an alternative exemplary embodiment of a passive mixer circuit. The mixer circuit shown in FIG. 6 is similar to the mixer circuit shown in FIG. 3. Elements in FIG. 6 that are identical to elements in FIG. 3 are identically numbered. In FIG. 6 the values of the resistances 651, 653, 655, 657, 661, 663, 665 and 667 are fixed and the resistances 652 (R_{2_ip}), 656 (R_{2_im}), 662 (R_{2_qp}) and 666 (R_{2_qm}) are adjustable.

In this example, the values of the resistances 652 (R_{2_ip}) and 656 (R_{2_im}) are simultaneously swept to determine a maximum harmonic rejection and using that value, the values of the resistances 662 (R_{2_qp}) and 666 (R_{2_qm}) are then simultaneously swept to determine a maximum harmonic rejection. These resistance values are then stored and used as described above.

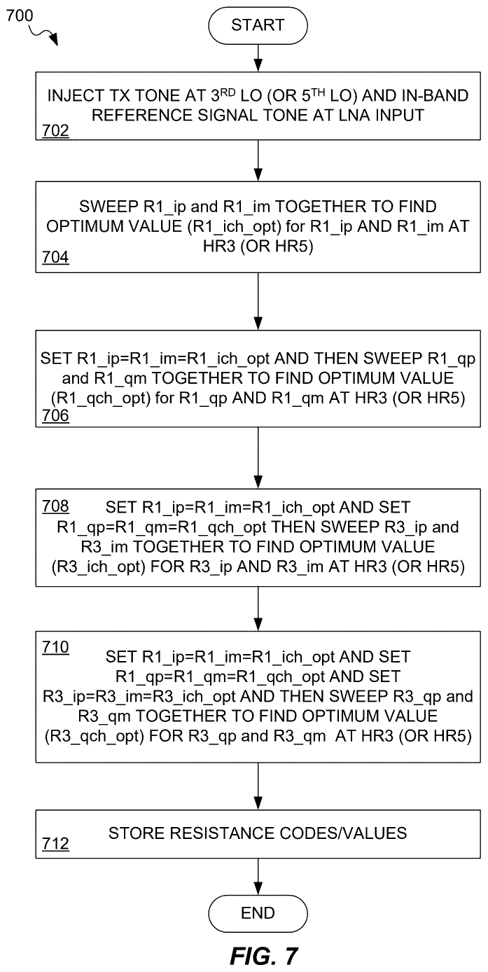

FIG. 7 is a flow chart 700 describing an example of the operation of a method for performing harmonic rejection calibration. The blocks in the method 700 can be used to perform, for example, third order LO harmonic (HR3) or fifth order LO harmonic (HR5), and in this example, will describe a method for performing HR3 calibration. The blocks in the method 700 can be performed in or out of the order shown, and in some embodiments, can be performed at least in part in parallel.

In block 702, a Tx tone is injected at the input of the LNA 302 at the third order LO for HR3 calibration (or at the fifth order LO for HR5 calibration) along with an in-band signal reference tone. For example, the transmitter 230 of FIGS. 2A, 2B or 2C can be configured to inject the Tx tone and the in-band reference tone to the receiver 250. In an exemplary embodiment, the Tx tone is injected at the 3^{rd} LO (or 5^{th} LO) and the in-band reference signal tone is injected in-band. In this manner, including the in-band reference signal tone allows the HR3 (or HR5) to be measured in dB with respect to the Tx tone. In the absence of the in-band reference signal tone the absolute power of the HR3 (or HR5) is measured in dBm.

In block 704, the values of the resistances 351 (R_{1_ip}) and 355 (R_{1_im}) are then simultaneously swept to find the optimum HR3 by analyzing the output of the ADC 385. The optimum resistance value at the optimum HR3 is referred to as R_{1_ich_opt}. The optimum value, R_{1_ich_opt}, for the resistance 351 (R_{1_ip}) and the resistance 355 (R_{1_im}) is then set.

In block 706, the resistance value of resistances 351 (R_{1_ip}) and 355 (R_{1_im}) are set to the optimum value R_{1_ich_opt} found previously in block 704 and then the values of the resistances 361 (R_{1_qp}) and 365 (R_{1_qm}) are then simultaneously swept to find the optimum HR3 by analyzing the output of the ADC 392. The optimum resistance value at the optimum HR3 is referred to as R_{1_qch_opt}. The optimum value, R_{1_qch_opt}, for the resistance 361 (R_{1_qp}) and the resistance 365 (R_{1_qm}) is then set.

In block 708, the resistance value of resistances 351 (R_{1_ip}) and 355 (R_{1_im}) are set to the optimum value R_{1_ich_opt} found previously in block 704 and the resistance value of resistances 361 (R_{1_qp}) and 365 (R_{1_qm}) are set to the optimum value R_{1_qch_opt} found previously in block 706 then the values of the resistance 353 (R_{3_ip}) and the resistance 357 (R_{3_im}) are then simultaneously swept to find the optimum HR3 by analyzing the output of the ADC 385. The optimum resistance value at the optimum HR3 is referred to as R_{3_ich_opt}.

In block 710, the resistance value of resistances 351 (R_{1_ip}) and 355 (R_{1_im}) are set to the optimum value R_{1_ich_opt} found previously in block 704, the resistance value of resistances 361 (R_{1_qp}) and 365 (R_{1_qm}) are set to the optimum value R_{1_qch_opt} found previously in block 706, and the resistance value of resistances 353 (R_{3_ip}) and 357 (R_{3_im}) are set to the optimum value R_{3_ich_opt} found previously in block 708, then the values of the resistance 363 (R_{3_qp}) and the resistance 367 (R_{3_qm}) are then simultaneously swept to find the optimum HR3 by analyzing the output of the ADC 385. The optimum resistance value at the optimum HR3 is referred to as R_{3_qch_opt}.

In block 712, the calibrated resistor codes/values corresponding to the optimum harmonic rejection are stored in a lookup table for various bands and be used as a per-part calibration or a static lookup table for all parts. For example, the calibrated resistor codes/values can be stored in a lookup table in the memory location 299.

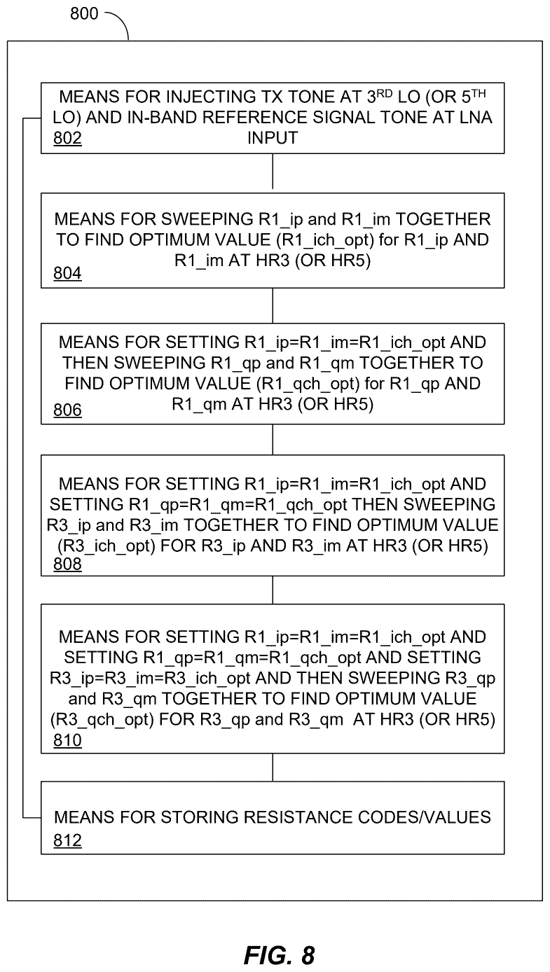

FIG. 8 is a functional block diagram of an apparatus 800 for performing harmonic rejection calibration. The apparatus 800 comprises means 802 for injecting a Tx tone at the third order LO for HR3 calibration (or at the fifth order LO for HR5 calibration) along with an in-band signal reference tone. In certain embodiments, the means 802 for injecting a Tx tone at the third order LO for HR3 calibration (or at the fifth order LO for HR5 calibration) along with an in-band signal reference tone can be configured to perform one or more of the functions described in operation block 702 of method 700 (FIG. 7). In an exemplary embodiment, the means 802 for injecting a Tx tone at the third order LO for HR3 calibration (or at the fifth order LO for HR5 calibration) along with an in-band signal reference tone may comprise the transmitter 230 of FIGS. 2A, 2B or 2C injecting the Tx tone and the in-band reference tone to the LNA 302 in the receiver 250. In an exemplary embodiment, the Tx tone is injected at the 3^{rd} LO (or 5^{th} LO) and the in-band reference signal tone is injected in-band.

The apparatus 800 also comprises means 804 for sweeping the values of the resistances 351 (R_{1_ip}) and 355 (R_{1_im}) to find the optimum HR3. In certain embodiments, the means 804 for sweeping the values of the resistances 351 (R_{1_ip}) and 355 (R_{1_im}) to find the optimum HR3 can be configured to perform one or more of the functions described in operation block 704 of method 700 (FIG. 7). In an exemplary embodiment, the means 804 for sweeping the values of the resistances 351 (R_{1_ip}) and 355 (R_{1_im}) to find the optimum HR3 may comprise sweeping the values of the resistances 351 (R_{1_ip}) and 355 (R_{1_im}) to find the optimum HR3 by analyzing the output of the ADC 385. The optimum value, R_{1_ich_opt}, for the resistance 351 (R_{1_ip}) and the resistance 355 (R_{1_im}) is then set.

The apparatus 800 also comprises means 806 for setting the resistance value of resistances 351 (R_{1_ip}) and 355 (R_{1_im}) to the optimum value R_{1_ich_opt} and then sweeping the values of the resistances 361 (R_{1_qp}) and 365 (R_{1_qm}) to find the optimum HR3. In certain embodiments, the means 806 for setting the resistance value of resistances 351 (R_{1_ip}) and 355 (R_{1_im}) to the optimum value R_{1_ich_opt} and then sweeping the values of the resistances 361 (R_{1_qp}) and 365 (R_{1_qm}) to find the optimum HR3 can be configured to perform one or more of the functions described in operation block 706 of method 700 (FIG. 7). In an exemplary embodiment, the means 806 for setting the resistance value of resistances 351 (R_{1_ip}) and 355 (R_{1_im}) to the optimum value R_{1_ich_opt} and then sweeping the values of the resistances 361 (R_{1_qp}) and 365 (R_{1_qm}) to find the optimum HR3 may comprise sweeping the values of the resistances 361 (R_{1_qp}) and 365 (R_{1_qm}) to find the optimum HR3 by analyzing the output of the ADC 392. The optimum value, R_{1_qch_opt}, for the resistance 361 (R_{1_qp}) and the resistance 365 (R_{1_qm}) is then set.

The apparatus 800 also comprises means 808 for setting the resistance value of resistances 351 (R_{1_ip}) and 355 (R_{1_im}) to the optimum value R_{1_ich_opt} and setting the resistance value of resistances 361 (R_{1_qp}) and 365 (R_{1_qm}) to the optimum value R_{1_qch_opt} and then sweeping values of the resistance 353 (R_{3_ip}) and the resistance 357 (R_{3_im}) to find the optimum HR3. In certain embodiments, the means 808 for setting the resistance value of resistances 351 (R_{1_ip}) and 355 (R_{1_im}) to the optimum value R_{1_ich_opt} and setting the resistance value of resistances 361 (R_{1_qp}) and 365 (R_{1_qm}) to the optimum value R_{1_qch_opt} and then sweeping values of the resistance 353 (R_{3_ip}) and the resistance 357 (R_{3_im}) to find the optimum HR3 can be configured to perform one or more of the functions described in operation block 708 of method 700 (FIG. 7). In an exemplary embodiment, the means 808 for setting the resistance value of resistances 351 (R_{1_ip}) and 355 (R_{1_im}) to the optimum value R_{1_ich_opt} and setting the resistance value of resistances 361 (R_{1_qp}) and 365 (R_{1_qm}) to the optimum value R_{1_qch_opt} and then sweeping values of the resistance 353 (R_{3_ip}) and the resistance 357 (R_{3_im}) to find the optimum HR3 may comprise sweeping the values of the resistance 353 (R_{3_ip}) and the resistance 357 (R3_im) to find the optimum HR3 by analyzing the output of the ADC 385. The optimum resistance value at the optimum HR3 is referred to as R_{3_ich_opt}.

The apparatus 800 also comprises means 810 for setting the resistance value of resistances 351 (R_{1_ip}) and 355 (R_{1_im}) to the optimum value R_{1_ich_opt}, setting the resistance value of resistances 361 (R_{1_qp}) and 365 (R_{1_qm}) to the optimum value R_{1_qch_opt}, and setting the resistance value of resistances 353 (R_{3_ip}) and 357 (R_{3_im}) to the optimum value R_{3_ich_opt}, then sweeping the values of the resistance 363 (R_{3_qp}) and the resistance 367 (R_{3_qm}) to find the optimum HR3. In certain embodiments, the means 810 for setting the resistance value of resistances 351 (R_{1_ip}) and 355 (R_{1_im}) to the optimum value R_{1_ich_opt}, setting the resistance value of resistances 361 (R_{1_qp}) and 365 (R_{1_qm}) to the optimum value R_{1_qch_opt}, and setting the resistance value of resistances 353 (R_{3_ip}) and 357 (R_{3_im}) to the optimum value R_{3_ich_opt}, then sweeping the values of the resistance 363 (R_{3_qp}) and the resistance 367 (R_{3_qm}) to find the optimum HR3 can be configured to perform one or more of the functions described in operation block 710 of method 700 (FIG. 7). In an exemplary embodiment, the means 810 for setting the resistance value of resistances 351 (R_{1_ip}) and 355 (R_{1_im}) to the optimum value R_{1_ich_opt}, setting the resistance value of resistances 361 (R_{1_qp}) and 365 (R_{1_qm}) to the optimum value R_{1_qch_opt}, and setting the resistance value of resistances 353 (R_{3_ip}) and 357 (R_{3_im}) to the optimum value R_{3_ich_opt}, then sweeping the values of the resistance 363 (R_{3_qp}) and the resistance 367 (R_{3_qm}) to find the optimum HR3 may comprise sweeping the values of the resistance 363 (R_{3_qp}) and the resistance 367 (R_{3_qm}) to find the optimum HR3 by analyzing the output of the ADC 385. The optimum resistance value at the optimum HR3 is referred to as R_{3_qch_opt}.

The apparatus 800 also comprises means 812 for storing the calibrated resistor codes/values in a lookup table. In certain embodiments, the means 812 for storing the calibrated resistor codes/values in a lookup table can be configured to perform one or more of the functions described in operation block 712 of method 700 (FIG. 7). In an exemplary embodiment, the means 812 for storing the calibrated resistor codes/values in a lookup table may comprise storing the calibrated resistor codes/values in a lookup table in the memory location 299.

Implementation examples are described in the following numbered clauses:
1. A passive mixer, comprising: an in-phase (I) mixer and a quadrature (Q) mixer configured to receive a single-ended communication signal from a low noise amplifier (LNA); an in-phase (I) local oscillator (LO) signal provided to the I mixer and a quadrature (Q) LO signal applied to the Q mixer; a first pair of I resistance banks connected to selected outputs of the I mixer; and a second pair of Q resistance banks connected to selected outputs of the Q mixer, wherein the first pair of I resistance banks comprises an I+ resistance bank having at least one adjustable I+ resistance and an I− resistance bank having at least one adjustable I− resistance; and the second pair of Q resistance banks comprises a Q+ resistance bank having at least one adjustable Q+ resistance and a Q− resistance bank having at least one adjustable Q− resistance.
2. The passive mixer of clause 1, wherein the first (I+) resistance bank comprises a first adjustable I+ resistance, a second fixed resistance, and a third adjustable I+ resistance; and the second (I−) resistance bank comprises a first adjustable I-resistance, a second fixed resistance, and a third adjustable I− resistance.
3. The passive mixer of clause 2, wherein resistance values of the first adjustable I+ resistance and the first adjustable I− resistance are simultaneously swept to determine a resistance value corresponding to a maximum harmonic rejection; and resistance values of the third adjustable I+ resistance and the third adjustable I− resistance are simultaneously swept to determine a resistance value corresponding to a maximum harmonic rejection.
4. The passive mixer of any of clauses 2 through 3, wherein the first (I+) resistance bank comprises a first fixed resistance, a second adjustable I+ resistance, and a third fixed resistance; and the second (I−) resistance bank comprises a first fixed resistance, a second adjustable I− resistance, and a third fixed resistance.
5. The passive mixer of any of clauses 2 through 4, wherein the first (Q+) resistance bank comprises a first adjustable Q+ resistance, a second fixed resistance, and a third adjustable Q+ resistance; and the second (Q−) resistance bank comprises a first adjustable Q− resistance, a second fixed resistance, and a third adjustable Q− resistance.
6. The passive mixer of clause 5, wherein resistance values of the first adjustable Q+ resistance and the first adjustable Q− resistance are simultaneously swept to determine a resistance value corresponding to a maximum harmonic rejection; and resistance values of the third adjustable Q+ resistance and the third adjustable Q− resistance are simultaneously swept to determine a resistance value corresponding to a maximum harmonic rejection.
7. The passive mixer of any of clauses 2 through 6, wherein the first (Q+) resistance bank comprises a first fixed resistance, a second adjustable Q+ resistance, and a third fixed resistance; and the second (Q−) resistance bank comprises a first fixed resistance, a second adjustable Q− resistance, and a third fixed resistance.
8. A method for harmonic signal rejection, comprising providing a transmit (Tx) signal and a reference tone to a low noise amplifier; providing a single-ended communication signal from the low noise amplifier (LNA) to an in-phase (I) mixer and a quadrature (Q) mixer; providing an in-phase (I) local oscillator (LO) signal to the I mixer and a quadrature (Q) LO signal applied to the Q mixer; simultaneously sweeping a resistance value of at least one I+ resistance and at least one I− resistance to determine a resistance value corresponding to a maximum I harmonic rejection; and simultaneously sweeping a resistance value of at least one Q+ resistance and at least one Q− resistance to determine a resistance value corresponding to a maximum Q harmonic rejection.
9. The method of clause 8, further comprising: simultaneously sweeping resistance values of a first adjustable first I+ resistance and a first adjustable I− resistance to determine a resistance value corresponding to a maximum harmonic rejection; simultaneously sweeping resistance values of a third adjustable I+ resistance and a third adjustable I− resistance to determine a resistance value corresponding to a maximum harmonic rejection; simultaneously sweeping resistance values of a first adjustable Q+ resistance and a first adjustable Q− resistance to determine a resistance value corresponding to a maximum harmonic rejection; and simultaneously sweeping resistance values of a third adjustable Q+ resistance and a third adjustable Q− resistance to determine a resistance value corresponding to a maximum harmonic rejection.
10. The method of any of clauses 8 through 9, further comprising: connecting a first pair of I resistance banks to selected outputs of the I mixer; and connecting a second pair of Q resistance banks to selected outputs of the Q mixer.
11. The method of any of clauses 9 through 10, further comprising setting a resistance value corresponding to a maximum harmonic rejection for an I channel to R_{1_ich_opt} and R_{3_ich_opt}; and setting a resistance value corresponding to a maximum harmonic rejection for a Q channel to R_{1_qch_opt} and R_{3_qch_opt}.
12. The method of any of clauses 8 through 11, wherein the Tx signal is an out-of-band tone and the reference tone is an in-band tone.
13. The method of clause 12, wherein injecting the Tx tone at the 3^{rd} LO (or 5^{th} LO) and injecting the in-band reference signal tone allows the harmonic rejection to be measured in dB with respect to the Tx tone.
14. An apparatus for harmonic signal rejection, comprising: means for providing a transmit (Tx) signal and a reference tone to a low noise amplifier; means for providing a single-ended communication signal from the low noise amplifier (LNA) to an in-phase (I) mixer and a quadrature (Q) mixer; means for providing an in-phase (I) local oscillator (LO) signal to the I mixer and a quadrature (Q) LO signal applied to the Q mixer; means for simultaneously sweeping a resistance value of at least one I+ resistance and at least one I− resistance to determine a resistance value corresponding to a maximum I harmonic rejection; and means for simultaneously sweeping a resistance value of at least one Q+ resistance and at least one Q− resistance to determine a resistance value corresponding to a maximum Q harmonic rejection.
15. The apparatus of clause 14, further comprising: means for simultaneously sweeping resistance values of a first adjustable first I+ resistance and a first adjustable I− resistance to determine a resistance value corresponding to a maximum harmonic rejection; means for simultaneously sweeping resistance values of a third adjustable I+ resistance and a third adjustable I− resistance to determine a resistance value corresponding to a maximum harmonic rejection; means for simultaneously sweeping resistance values of a first adjustable Q+ resistance and a first adjustable Q− resistance to determine a resistance value corresponding to a maximum harmonic rejection; and means for simultaneously sweeping resistance values of a third adjustable Q+ resistance and a third adjustable Q-resistance to determine a resistance value corresponding to a maximum harmonic rejection.
16. The apparatus of any of clauses 14 through 15, further comprising: means for connecting a first pair of I resistance banks to selected outputs of the I mixer; and means for connecting a second pair of Q resistance banks to selected outputs of the Q mixer.
17. The apparatus of any of clauses 15 through 16, further comprising: means for setting a resistance value corresponding to a maximum harmonic rejection for an I channel to R_{1_ich_opt} and R_{3_ich_opt}; and means for setting a resistance value corresponding to a maximum harmonic rejection for a Q channel to R_{1_qch_opt} and R_{3_qch_opt}.
18. The apparatus of any of clauses 14 through 17, wherein the Tx signal is an out-of-band tone and the reference tone is an in-band tone.
19. The apparatus of clause 18, wherein injecting the Tx tone at the 3^{rd} LO (or 5^{th} LO) and injecting the in-band reference signal tone allows the harmonic rejection to be measured in dB with respect to the Tx tone.

The circuit architecture described herein described herein may be implemented on one or more ICs, analog ICs, RFICs, mixed-signal ICs, ASICs, printed circuit boards (PCBs), electronic devices, etc. The circuit architecture described herein may also be fabricated with various IC process technologies such as complementary metal oxide semiconductor (CMOS), N-channel MOS (NMOS), P-channel MOS (PMOS), bipolar junction transistor (BJT), bipolar-CMOS (BiCMOS), silicon germanium (SiGe), gallium arsenide (GaAs), heterojunction bipolar transistors (HBTs), high electron mobility transistors (HEMTs), silicon-on-insulator (SOI), etc.

An apparatus implementing the circuit described herein may be a stand-alone device or may be part of a larger device. A device may be (i) a stand-alone IC, (ii) a set of one or more ICs that may include memory ICs for storing data and/or instructions, (iii) an RFIC such as an RF receiver (RFR) or an RF transmitter/receiver (RTR), (iv) an ASIC such as a mobile station modem (MSM), (v) a module that may be embedded within other devices, (vi) a receiver, cellular phone, wireless device, handset, or mobile unit, (vii) etc.

Although selected aspects have been illustrated and described in detail, it will be understood that various substitutions and alterations may be made therein without departing from the spirit and scope of the present invention, as defined by the following claims.

What is claimed is:

1. A passive mixer, comprising:
an in-phase (I) mixer and a quadrature (Q) mixer configured to receive a single-ended communication signal from a low noise amplifier (LNA);
an in-phase (I) local oscillator (LO) signal provided to the I mixer and a quadrature (Q) LO signal applied to the Q mixer;
a first pair of I resistance banks connected to selected outputs of the I mixer; and
a second pair of Q resistance banks connected to selected outputs of the Q mixer,
wherein the first pair of I resistance banks comprises an I+ resistance bank having at least one adjustable I+ resistance and an I− resistance bank having at least one adjustable I− resistance; and
the second pair of Q resistance banks comprises a Q+ resistance bank having at least one adjustable Q+ resistance and a Q− resistance bank having at least one adjustable Q− resistance.

2. The passive mixer of claim 1, wherein the first (I+) resistance bank comprises a first adjustable I+ resistance, a second fixed resistance, and a third adjustable I+ resistance; and
the second (I−) resistance bank comprises a first adjustable I− resistance, a second fixed resistance, and a third adjustable I− resistance.

3. The passive mixer of claim 2, wherein resistance values of the first adjustable I+ resistance and the first adjustable I− resistance are simultaneously swept to determine a resistance value corresponding to a maximum harmonic rejection; and
resistance values of the third adjustable I+ resistance and the third adjustable I− resistance are simultaneously swept to determine a resistance value corresponding to a maximum harmonic rejection.

4. The passive mixer of claim 1, wherein the first (I+) resistance bank comprises a first fixed resistance, a second adjustable I+ resistance, and a third fixed resistance; and
the second (I−) resistance bank comprises a first fixed resistance, a second adjustable I− resistance, and a third fixed resistance.

5. The passive mixer of claim 1, wherein the first (Q+) resistance bank comprises a first adjustable Q+ resistance, a second fixed resistance, and a third adjustable Q+ resistance; and
the second (Q−) resistance bank comprises a first adjustable Q− resistance, a second fixed resistance, and a third adjustable Q− resistance.

6. The passive mixer of claim 5, wherein resistance values of the first adjustable Q+ resistance and the first adjustable Q− resistance are simultaneously swept to determine a resistance value corresponding to a maximum harmonic rejection; and
resistance values of the third adjustable Q+ resistance and the third adjustable Q− resistance are simultaneously swept to determine a resistance value corresponding to a maximum harmonic rejection.

7. The passive mixer of claim 1, wherein the first (Q+) resistance bank comprises a first fixed resistance, a second adjustable Q+ resistance, and a third fixed resistance; and
the second (Q−) resistance bank comprises a first fixed resistance, a second adjustable Q− resistance, and a third fixed resistance.

8. A method for harmonic signal rejection, comprising:
providing a transmit (Tx) signal and a reference tone to a low noise amplifier;
providing a single-ended communication signal from the low noise amplifier (LNA) to an in-phase (I) mixer and a quadrature (Q) mixer;
providing an in-phase (I) local oscillator (LO) signal to the I mixer and a quadrature (Q) LO signal applied to the Q mixer;
simultaneously sweeping a resistance value of at least one I+ resistance and at least one I− resistance to determine a resistance value corresponding to a maximum I harmonic rejection; and
simultaneously sweeping a resistance value of at least one Q+ resistance and at least one Q− resistance to determine a resistance value corresponding to a maximum Q harmonic rejection.

9. The method of claim 8, further comprising:
simultaneously sweeping resistance values of a first adjustable first I+ resistance and a first adjustable I− resistance to determine a resistance value corresponding to a maximum harmonic rejection;
simultaneously sweeping resistance values of a third adjustable I+ resistance and a third adjustable I− resistance to determine a resistance value corresponding to a maximum harmonic rejection;
simultaneously sweeping resistance values of a first adjustable Q+ resistance and a first adjustable Q− resistance to determine a resistance value corresponding to a maximum harmonic rejection; and
simultaneously sweeping resistance values of a third adjustable Q+ resistance and a third adjustable Q− resistance to determine a resistance value corresponding to a maximum harmonic rejection.

10. The method of claim 8, further comprising:
connecting a first pair of I resistance banks to selected outputs of the I mixer; and
connecting a second pair of Q resistance banks to selected outputs of the Q mixer.

11. The method of claim 9, further comprising
setting a resistance value corresponding to a maximum harmonic rejection for an I channel to R_{1_ich_opt} and R_{3_ich_opt}; and
setting a resistance value corresponding to a maximum harmonic rejection for a Q channel to R_{1_qch_opt} and R_{3_qch_opt}.

12. The method of claim 8, wherein the Tx signal is an out-of-band tone and the reference tone is an in-band tone.

13. The method of claim 12, wherein injecting the Tx tone at the 3^{rd} LO (or 5^{th} LO) and injecting the in-band reference signal tone allows the harmonic rejection to be measured in dB with respect to the Tx tone.

14. An apparatus for harmonic signal rejection, comprising:
means for providing a transmit (Tx) signal and a reference tone to a low noise amplifier;
means for providing a single-ended communication signal from the low noise amplifier (LNA) to an in-phase (I) mixer and a quadrature (Q) mixer;
means for providing an in-phase (I) local oscillator (LO) signal to the I mixer and a quadrature (Q) LO signal applied to the Q mixer;
means for simultaneously sweeping a resistance value of at least one I+ resistance and at least one I− resistance to determine a resistance value corresponding to a maximum I harmonic rejection; and
means for simultaneously sweeping a resistance value of at least one Q+ resistance and at least one Q− resistance to determine a resistance value corresponding to a maximum Q harmonic rejection.

15. The apparatus of claim 14, further comprising:
means for simultaneously sweeping resistance values of a first adjustable first I+ resistance and a first adjustable I− resistance to determine a resistance value corresponding to a maximum harmonic rejection;
means for simultaneously sweeping resistance values of a third adjustable I+ resistance and a third adjustable I− resistance to determine a resistance value corresponding to a maximum harmonic rejection;
means for simultaneously sweeping resistance values of a first adjustable Q+resistance and a first adjustable Q-resistance to determine a resistance value corresponding to a maximum harmonic rejection; and
means for simultaneously sweeping resistance values of a third adjustable Q+ resistance and a third adjustable Q− resistance to determine a resistance value corresponding to a maximum harmonic rejection.

16. The apparatus of claim 14, further comprising:
means for connecting a first pair of I resistance banks to selected outputs of the I mixer; and
means for connecting a second pair of Q resistance banks to selected outputs of the Q mixer.

17. The apparatus of claim 15, further comprising:
means for setting a resistance value corresponding to a maximum harmonic rejection for an I channel to R_{1_ich_opt} and R_{3_ich_opt}; and
means for setting a resistance value corresponding to a maximum harmonic rejection for a Q channel to R_{1_qch_opt} and R_{3_qch_opt}.

18. The apparatus of claim 14, wherein the Tx signal is an out-of-band tone and the reference tone is an in-band tone.

19. The apparatus of claim 18, wherein injecting the Tx tone at the 3^{rd} LO (or 5^{th} LO) and injecting the in-band reference signal tone allows the harmonic rejection to be measured in dB with respect to the Tx tone.
